(19) United States
(12) Patent Application Publication
(10) Pub. No.: US 2013/0062181 A1
(43) Pub. Date: Mar. 14, 2013

(54) TOUCH SWITCH

(71) Applicants: Katsushi TOKURA, Mobara-shi (JP); Eiji MORIMOTO, Mobara-shi (JP)

(72) Inventors: Katsushi TOKURA, Mobara-shi (JP); Eiji MORIMOTO, Mobara-shi (JP)

(21) Appl. No.: 13/611,401

(22) Filed: Sep. 12, 2012

(30) Foreign Application Priority Data
Sep. 12, 2011 (JP) 2011-198594

(51) Int. Cl. H03K 17/98

(52) U.S. Cl. 200/600

(57) ABSTRACT

A touch switch includes a glass substrate; a lattice pattern formed on the glass substrate by a plurality of first line wirings and a plurality of second line wirings; and a non-transparent insulating member formed on the first line wirings and the second line wirings. The plurality of first line wirings are arranged at a predetermined interval. The plurality of second line wirings are arranged at a predetermined interval to intersect the first line wirings. The sensor units and dummy sensor units are formed to be electrically isolated from each other and adjacent to each other by separators provided in the first and second line wirings of the lattice pattern. Marks are formed by the non-transparent insulating member and a transparent opening section, the marks being arranged in positions corresponding to the sensor units.

### FIELD OF THE INVENTION

The present invention relates to a touch switch (also known as a touch key or a touch sensor) for detecting an approach of an operator's finger, hand and the like to a portion corresponding to an electrode based on a change in electrostatic capacitance. More particularly, the present invention relates to a touch switch with a reduced number of parts and a prominent appearance.

### BACKGROUND OF THE INVENTION

A capacitive touch switch is disclosed in Japanese Utility Model Application Publication No. H2-128336. As shown in FIGS. 8A and 8B, the disclosed touch switch includes a manipulation panel 101 having a plurality of contact segments (hereinafter referred to as “key areas”) 102 corresponding to manipulation keys; and a multi-layered substrate 103 which lies beneath the manipulation panel 101 and has conductive patterns 104 stacked in a concentric relationship with the key areas 102, the conductive patterns 104 corresponding to detectors of capacitive switch elements. When a key area 102 on the manipulation panel 101 is touched by an operator's fingertip, a capacitive switch element corresponding to a conductive pattern 104 of the touched key area 102 can be operated.

However, such a conventional touch switch as shown in FIG. 9 has a problem in that the number of parts is increased since it requires the manipulation panel 101 on which certain marks (e.g., 0, #, etc. of the key areas 102 are formed and the multi-layered substrate 103 on which the conductive patterns 104 corresponding to the detectors of the capacitive switch elements are formed, separately. In addition, there is an additional problem in that the marks of the key areas 102 are abraded due to touch of the key areas 102 by the operator's fingertip, thereby deteriorating the prominent appearance.

### SUMMARY OF THE INVENTION

In view of the above, the present invention provides a touch switch with a reduced number of parts and a prominent appearance.

In accordance with an aspect of the present invention, there is provided a touch switch, including: a glass substrate; a lattice pattern formed on the glass substrate by a plurality of first line wirings and a plurality of second line wirings; and a non-transparent insulating member formed on the first line wirings and the second line wirings, wherein the plurality of first line wirings are arranged at a predetermined interval, the plurality of second line wirings are arranged at a predetermined interval to intersect the first line wirings, sensor units and dummy sensor units are formed to be electrically isolated from each other and adjacent to each other by separators provided in the first and second line wirings of the lattice pattern, marks are formed by the non-transparent insulating member and a transparent opening section, the marks being arranged in positions corresponding to the sensor units.

Accordingly, the less number of parts can be provided since the non-transparent (light-shielding) insulating member is integrated with the marks. In addition, since a surface in the opposite side to the surface of the glass substrate on which the metal thin film is formed is touched by an operator or the like, the marks can have a remarkable appearance without being abraded. Moreover, boundaries between electrodes are invisible, thereby providing a remarkable appearance. Besides, the non-transparent insulating member may serve as a protection member of the line wirings. Furthermore, since capacitance between adjacent electrodes can be reduced, it is possible to improve precision of touch decision for electrodes. Finally, since the marks are formed of the non-transparent insulating member, it is possible to form marks having a variety of shapes easily. Moreover, when the non-transparent insulating member is colored, it is possible to form marks having a variety of colors easily.

The marks may be formed by the insulating member and the opening section which is provided in the insulating member and has a shape corresponding to the marks.

The marks may be formed by the opening section and the insulating member which is provided in the opening section and has a shape corresponding to the marks.

The insulating member may include a first insulating member and a second insulating member, and the marks are formed by the first insulating member having a shape corresponding to the marks and the second insulating member provided around the first insulating member with the opening section interposed therebetween.

Accordingly, since the marks are formed by the insulating member and the opening section (a combination of an insulating member, an opening section, an insulating member having a shape corresponding to a mark (predetermined design), and an opening section having a shape corresponding to a mark (predetermined design)), marks having various shapes and various combinations of marks can be formed with ease and convenience to a customer's taste.

The separators may be provided in the first line wirings, and one separated ends of the separated first wirings may be adjacent to the other separated ends of the separated first line wirings or one of the second line wirings with the separators interposed therebetween.

The separators may be provided in the plurality of second line wirings, and one separated ends of the separated second wirings may be adjacent to the other separated ends of the separated second line wirings or one of the first line wirings with the separators interposed therebetween.

The separators may be provided in the first line wirings or the second line wirings, leading-out wirings of the sensor units may be connected to the line wirings constituting the sensor units and may be led out of the dummy sensor units via the separators, the leading-out wirings of the sensor units being adjacent to one separated ends of the first line wirings or one separated ends of the second line wirings with the separators interposed therebetween.

Accordingly, since separated ends of various line wirings (the first line wirings, the second line wirings, the leading-out wirings of the sensor units) are adjacent to each other or one ends of line wirings are adjacent to other one of line wirings with the separators interposed therebetween, it is possible to reduce capacitance between various line wirings. In particular, there is a need to make the separators as narrow as possible in order to make the separators invisible to provide a remarkable appearance. In this case, since capacitance between various line wirings is increased, it is advantageous to use these electrode structures.

A coating film may be provided on an opposite surface of the glass substrate to a surface on which the sensor units are formed, the coating film being made of resin into which beads are mixed, with at least some of the beads being exposed to a surface of the coating film.

Accordingly, since the coating film made of resin into which beads are mixed is provided on the surface in the opposite side to the surface on which the sensor unit of the glass substrate is formed, with at least some of the beads being exposed to the surface of the coating film, and is in a pseudo-etched (diffused surface-reflected) state, a fingerprint made by an operator's touch can be unlikely to be visible and reflection by the metal thin film can be prevented, which can result in a remarkable appearance. In addition, fine unevenness formed on the outer surface of the glass substrate 2 can improve an operator's touch sense.

A plurality of connection terminals may be provided to connect an external connection member to the leading-out wirings and the dummy sensor units, and the sensor units, the dummy sensor units, the leading-out wirings of the sensor units, and the connection terminals on the glass substrate may be made of the same metal thin film.

Accordingly, since all metal thin films on the glass substrate including the sensor units, the dummy sensor units, the leading-out wirings of the sensor units, and the connection terminals are made of the same metal material, product costs can be controlled without increasing the number of kinds of materials. In addition, since the sensor unit and the dummy electrode can be formed of the metal thin film in a lump (i.e., in the same manufacturing process), they can be manufactured with ease and convenience.

The touch switch may further includes light sources which illuminate the marks with light and may be arranged to correspond to the marks.

Accordingly, since the touch switch further includes the light sources which illuminate the marks with light and are arranged to correspond to the marks, the marks can be easily visible and checked. In addition, a form of display of the marks can be selected to a customer's taste, such as according to whether light transmits through the marks, or marks through which light does not transmit are brought in relief.

The light sources may emit light with different colors and sequentially change light colors of the switch electrodes decided to be touched.

Accordingly, since the light sources emit lights with different colors and sequentially change light colors of the sensor units decided to be touched, the marks can be easily visible and checked and the sensor units decided to be touched can be easily discerned.

In a state where all of the light sources emit light of a predetermined color, a light source corresponding to the switch electrode decided as being touched may emit light of a different color.

Accordingly, since, with all of the light sources emitting light with a predetermined color, only a light source corresponding to sensor units decided to be touched emits light of a different color, the marks can be easily visible and checked and the sensor units decided to be touched can be easily discerned.

A non-emission member having a color different from those of the metal thin film may be formed on a rear surface of the marks.

Accordingly, since the non-emission member having a color different from that of the metal thin film is formed on the rear surface of the marks, the marks can be easily visible and checked.

### BRIEF DESCRIPTION OF THE DRAWINGS

The objects and features of the present invention will become apparent from the following description of embodiments, given in conjunction with the accompanying drawings, in which:

FIG. 1 is a plan view of a touch switch in accordance with an embodiment of the present invention;

FIG. 2 is a cross sectional view of the touch switch, taken along line II-II in FIG. 1;

FIG. 3 is a cross sectional view of the touch switch, taken along line III-III in FIG. 1;

FIG. 4 is a partially enlarged view of the touch switch in a Z region of FIG. 1;

FIGS. 5A to 5C are partially enlarged views of the touch switch shown in FIG. 1;

FIG. 6 is a cross sectional view of the touch switch;

FIG. 7 explains the principle of operation of the touch switch;

FIG. 8 is a circuit diagram of the touch switch; and

FIGS. 9A and 9B show an example configuration of a conventional touch switch.

### DETAILED DESCRIPTION OF THE EMBODIMENTS

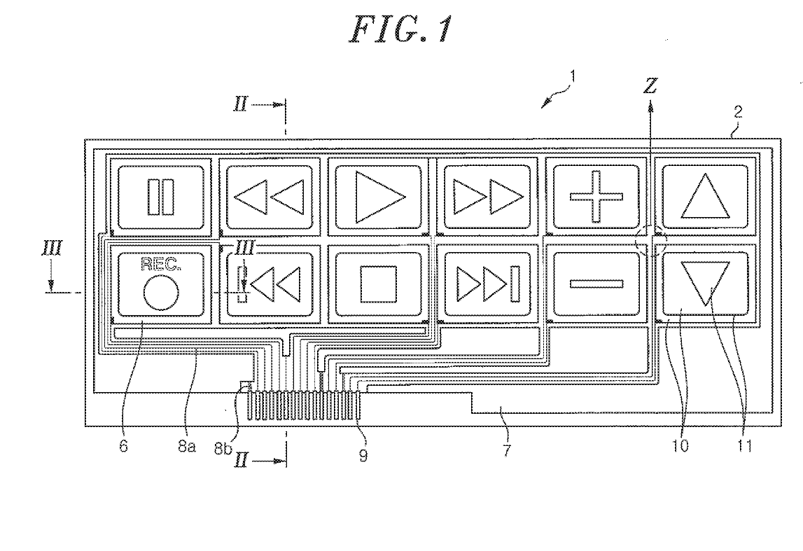

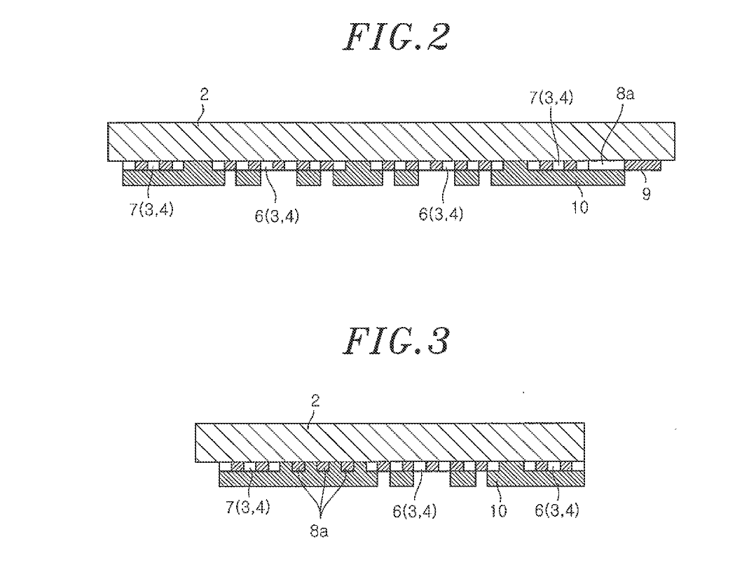

A touch switch in accordance with an embodiment of the present invention will now be described with reference to FIGS. 1 to 8 which form a part hereof. Throughout the drawings, the illustration of certain members which have no direct relationship with the present invention or are not essential to explain the corresponding drawing will be omitted. Further, it is the principle to denote a reference numeral to only one of a plurality of same elements, if any, in the same figure.

As shown in FIGS. 1 to 3, a touch switch 1 includes a plurality of sensor units 6 and a plurality of dummy sensor units 7, which are formed by providing separators 5 in a lattice pattern of first line wirings 3 and second line wirings 4. The shape of the pattern is not limited to the lattice pattern, and may be of, e.g., a honeycomb or polygonal pattern; leading-out wirings 8 including leading-out wirings 8a of the sensor units 6 whose one ends are connected to the respective sensor units 6 and leading-out wirings 8b of the dummy sensor units 7 whose one ends are connected to the respective dummy sensor units 7; and a plurality of connection terminals 9 to which the other ends of the leading-out wirings 8 are connected, all of which are formed (on the same plane) in an inner side of a glass substrate 2. The substrate 2 is not limited to the glass substrate, and may be any transparent or semi-transparent substrate. These wirings and terminals (the sensor units 6, the dummy sensor units 7, the leading-out wirings 8 and the connection terminals 8) are formed of a metal thin film. In addition, a non-transparent insulating member 10 is formed on the top of these wirings and terminals (including the inner side of the glass substrate 2).

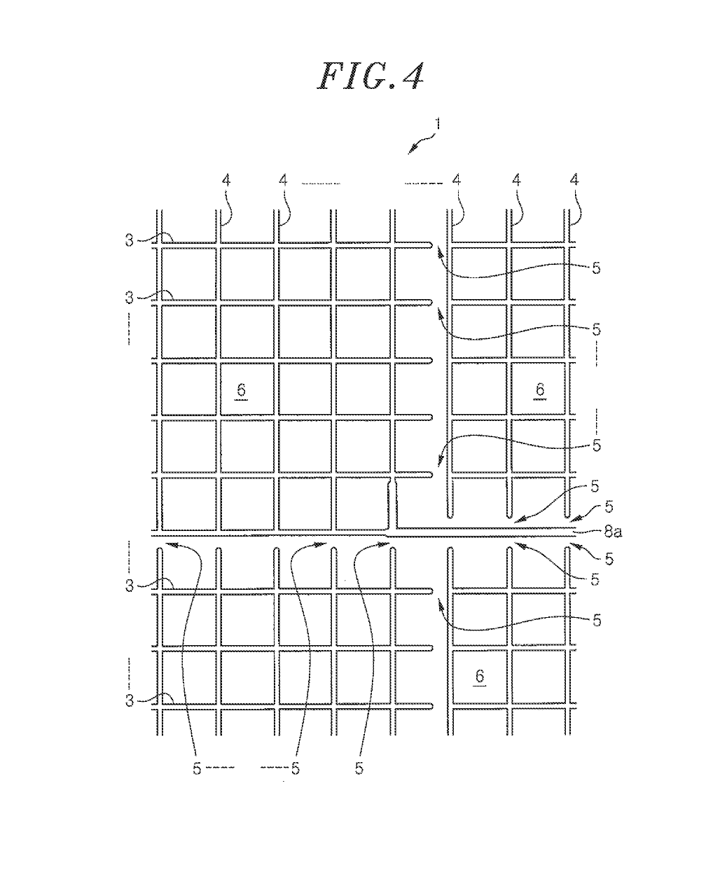

As shown in FIG. 4, an electrode structure of the touch switch 1 includes, as a basic pattern, a square lattice pattern having a plurality of first line wirings 3 arranged in parallel at predetermined intervals (wirings in parallel to the horizontal direction) and a plurality of second line wirings 4 arranged in parallel at the same intervals as the first line wirings 3 and perpendicular to the first line wirings 3 (wirings in parallel to the vertical direction). This lattice pattern is formed of a metal thin film (conductor) integrated on the inner side of the glass substrate 2 such that the plurality of sensor units 6 and the plurality of dummy sensors 7, which are electrically isolated from each other, are formed adjacent to each other by providing disconnected separators 5 in some of the line wirings. In addition, although it has been illustrated here that the plurality of first line wirings 3 and the plurality of second line wirings 4 are in parallel to each other, this is not meant to include only a geometrically completely parallel arrangement and exclude other arrangements. In other words, arrangements of patterns of parallel line wirings in embodiments may include some degrees of deviations from the parallelism for the reason of errors of wiring pattern designs or others.

That is, by providing separators 5 at the same horizontal positions of a plurality of adjacent first line wirings 3 and providing separators 5 at the same vertical positions of a plurality of adjacent second line wirings 4, the lattice pattern is divided into a region of sensor units 6 and a region of dummy sensor units 7, which are electrically isolated from each other, with the separators 5 of the first and second line wirings 3 and 4 as boundaries.

As shown in FIG. 1, 12 electrically-isolated sensor units 6 are arranged (in the form of a 6×2 matrix) at the central portion of the glass substrate 2. In addition, 4 dummy sensor units 7 are arranged around the sensor units 6 to surround the sensor units 6.

One of the four dummy sensor units 7 has a C-like shape and is connected to a first connection terminal 9 that is located first from the left through a corresponding leading-out wiring 8b. This dummy sensor units 7 faces 8 of the 12 sensor units 6. That is, this dummy sensor units 7 faces 3 two sides of each of the upper leftmost, the upper rightmost, and the lower rightmost sensor unit 6, via the separators 5. Likewise, this dummy sensor units 7 faces 5 one side of each of the 4 upper sensor units 6, except the upper leftmost and the upper rightmost sensor unit 6 via the separators 5, and also faces one side of the lower leftmost sensor unit 6, with leading-out wirings 8a interposed therebetween).

One of the 3 remaining dummy sensor units 7 is connected to a sixth-left connection terminal 9 through a corresponding leading-out wiring 8b. This dummy sensor units 7 faces 3 of the 12 sensor units 6. That is, this dummy electrode faces 3 one side (lower side) of the bottom first to third sensor units 6 from the left via the separators 5 therebetween.

Another one of the 3 remaining dummy sensor units 7 is connected to an eleventh-left connection terminal 8 through one leading-out 8b. This dummy sensor unit 7 faces one of the 12 sensor units 6. That is, this dummy electrode faces 1 one side (lower side) of the lower fourth-left sensor unit 6 from the left via the separators 5 therebetween. Likewise, the other of the 3 remaining dummy sensor units 7 is connected to a fourteenth-left connection terminal 9 through a corresponding leading-out 8b. This dummy electrode faces 1 one side (lower side) of the lower fifth-left sensor unit 6 from the left via the separators 5 therebetween.

Thus, each of sensor units 6 is adjacent to (faces) other sensor units 6 and dummy sensor units 7, with the separators 5 interposed therebetween. In addition, the outmost perimeter of the group of 12 sensor units 6 is adjacent to the 4 dummy sensor units 7. With such a configuration, there exist no electrodes and wirings with floating potentials around the sensor units 6, thereby preventing the malfunction of the sensor unit 6 effectively.

The dummy sensor units 7 are fixed to a ground potential or a predetermined potential (for example, the same potential as the sensor units 6). Accordingly, it is possible to prevent charges from be stored in the dummy sensor units 7 and prevent the sensor units 6 from malfunctioning. If the dummy sensor units 7 are not present, it may cause malfunction of the sensor units 6 when the glass substrate 2 is charged at a position adjacent to the sensor units 6.

12 leading-out wirings 8a of the sensor units 6 are arranged to correspond to the 12 sensor units 6. These leading-out wirings 8a are connected to line wirings 3 and 4 constituting the sensor units 6. In addition, the leading-out wirings 8a are led out of the dummy sensor units 7 and are connected to the connection terminals 9 via the respective separators 5 between two sensor units 6, between two dummy sensor units 7, or between the sensor units 6 and the dummy sensor units 7.

It is preferable that the leading-out wirings 8a are formed in a single line to reduce a capacitance and prevent a touch decision from being made in erroneous touch. The leading-out wirings 8a are set to be larger in width (thickness) than the line wirings 3 and 4. This allows a reduced probability of disconnection in a manufacturing process. In addition, some of the line wirings 3 and 4 constituting the sensor units 6 may be used as the leading-out wirings 8a.

As shown in FIG. 1, a first leading-out wiring 8a that is located first from the left has one end connected to an upper leftmost sensor unit 6 (one line wiring of the sensor units 6) at a lower left corner thereof and the other end connected to a second connection terminal 9 that is located second from the left.

Likewise, a second leading-out wiring 8a has one end connected to an upper second-left sensor unit 6 at a lower left corner thereof and the other end connected to a third connection terminal 9 that is located third from the left.

A third leading-out wiring 8a has one end connected to a lower second-left sensor unit 6 at an upper left corner thereof and the other end connected to a fourth connection terminal 8 that is located fourth from the left.

A fourth leading-out wiring 8a has one end connected to a lower leftmost sensor unit 6 at a lower left corner thereof and the other end connected to a fifth connection terminal 9 that is located fifth from the left.

A fifth leading-out wiring 8a has one end connected to a lower third-left sensor unit 6 at a lower right corner thereof and the other end connected to a seventh connection terminal 8 that is located seventh from the left.

A sixth leading-out wiring 8a has one end connected to an upper third-left sensor unit 6 at a lower right edge thereof and the other end connected to an eighth connection terminal 9 that is located eighth from the left.

A seventh leading-out wiring 8a has one end connected to an upper fourth-left sensor unit 6 at a lower left corner thereof and the other end connected to a ninth connection terminal 8 that is located ninth from the left.

An eighth leading-out wiring 8a has one end connected to a lower fourth-left sensor unit 6 at a lower left corner thereof and the other end connected to a tenth connection terminal 9 that is located tenth from the left.

A ninth leading-out wiring 8a has one end connected to an upper fifth-left sensor unit 6 at a lower left corner thereof and the other end connected to a twelfth connection terminal 9 that is located twelfth from the left.

A tenth leading-out wiring 8a has one end connected to a lower fifth-left sensor unit 6 at a lower left corner thereof and the other end connected to a thirteenth connection terminal 9 that is located thirteenth from the left.

A eleventh leading-out wiring 8a has one end connected to an upper-rightmost sensor unit 6 at a lower left corner thereof and the other end connected to a fifteenth connection terminal 9 that is located fifteenth from the left.

A twelfth leading-out wiring 8a has one end connected to a lower rightmost sensor unit 6 at a lower left corner thereof and the other end connected to a sixteenth connection terminal 9 that is located sixteenth from the left.

The dummy sensor units 7 include the leading-out wirings 8b. The leading-out wirings 8b are arranged to correspond to 4 dummy sensor units 7. Each of the leading-out wirings 8b has one end connected to one dummy sensor unit 7 (one line wiring of the dummy sensor units 7) and the other end connected to one connection terminal 9. Each of the leading-out wirings 8b is formed of a plurality of lines, each having a same thickness as that of the leading-out wiring 8a. Each leading-out wiring 8b may be formed of a single line which is equal to or more than that of the leading-out wiring 8a.

The leading-out wirings 8a are divided into sets of lines (e.g., two sets of 4 lines and two sets of 2 lines) to be connected to the connection terminals 9 with the leading-out wirings 8b interposed therebetween. This configuration can reduce an effect of noises caused by adjacent wirings as compared to the configuration where all the leading-out wirings 8a are arranged together adjacently to be connected to the connection terminals 9.

The following electrode structures are provided at boundaries between the above-configured sensor units 6 or at boundaries between the sensor units 6 and the dummy sensor units 7.

(1) When the separators 5 are provided in the plurality of first line wirings 3, one separated ends of the plurality of first line wirings 3 are adjacent to the other separated ends of the plurality of first line wirings 3 with the separators 5 interposed therebetween. Alternatively, one separated ends of the plurality of first line wirings 3 are adjacent to one of the plurality of second line wirings 4 with the separators 5 interposed therebetween.

(2) When the separators 5 are provided in the plurality of second line wirings 4, one separated ends of the plurality of second line wirings 4 are adjacent to the other separated ends of the plurality of second line wirings 4 with the separators 5 interposed therebetween. Alternatively, one separated ends of the plurality of second line wirings 4 are adjacent to one of the plurality of first line wirings 3 with the separators 5 interposed therebetween.

Similarly, the following electrode structures are provided at boundaries between the above-configured sensor units 6 and the leading-out wirings 8a or at boundaries between the dummy sensor units 7 and the leading-out wirings 8a.

(1) When the separators 5 are provided in the plurality of first line wirings 3 (the leading-out wirings 8a passing the separators 5 are in parallel to the plurality of second line wirings 4), the leading-out wirings 8a are adjacent to one separated ends of the plurality of first line wirings 3 with the separators 5 interposed therebetween.

(2) When the separators 5 are provided in the plurality of second line wirings 4 (the leading-out wirings 8a passing the separators 5 are in parallel to the plurality of first line wirings 3), the leading-out wirings 8a are adjacent to one separated ends of the plurality of second line wirings 4 with the separators 5 interposed therebetween.

For example, 16 connection terminals 9 are arranged to correspond to leading-out wirings 8a and 8b. Each of the connection terminals 9 has one end connected to the corresponding leading-out wiring 8a or leading-out wiring 8b and the other end thereof connected to an external connection member. The connection terminals 9 are also arranged parallelly close to one another at one side (lower side) of the circumference of the glass substrate 2. In addition, leading-out wirings 8a and 8b may serve as the connection terminals 9 as well.

The insulating member 10 is provided in the entire surface of the separators 5, the sensor units 6, the dummy sensor units 7 and the leading-out wirings 8 except the connection terminals 9. Accordingly, the insulating member 10 protects various wirings. In addition, the insulating member 10 serves as a mark 11.

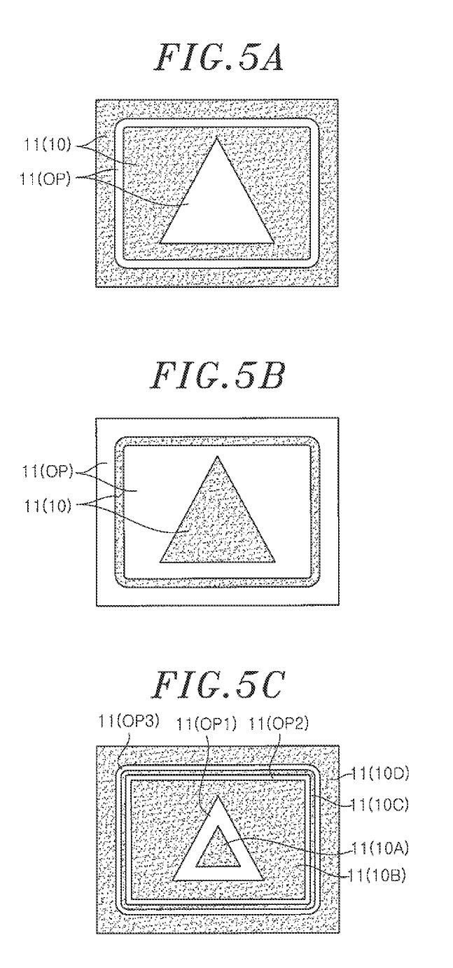

FIGS. 5A to 5C are enlarged view of the touch switch 1. As shown in FIG. 5, a mark 11 composed of an opening section OP and an insulating member 10 is provided at a position corresponding to each sensor unit 6. FIG. 5A is an enlarged view of the mark 11 located at the upper right side of FIG. 1. FIGS. 5B and 5C illustrate modifications of the mark 11 of FIG. 5A. In FIGS. 5A to 5C, only the mark 11 of the touch switch 1 shown in FIG. 1 are schematically shown and other electrodes and so on are not shown.

In FIG. 5A, the mark 11 includes the insulating member 10 and the opening section OP which is provided in the insulating member 10 and has a shape corresponding to the mark 11 (a shape corresponding to a predetermined design). The opening section OP has a triangular opening section OP formed at a corresponding position of the sensor unit 6 (center of the sensor unit 6) and a frame-like opening section OP formed therearound.

In FIG. 5B, the mark 11 includes the opening section OP and the insulating member 10 which is provided in the opening section OP and has a shape corresponding to the mark 11 (a shape corresponding to a predetermined design). The insulating member 10 has a triangular insulating member 10 formed at a corresponding position of the sensor unit 6 (center of the sensor unit 6) and a frame-like insulating member 10 formed therearound.

In FIG. 5C, the mark 11 includes a central insulating member 10A (first insulating member) which has a triangular shape (shape corresponding to a predetermined design), an insulating member 10B (second insulating member) provided around the insulating member 10A with an opening section OP1 interposed therebetween, an insulating member 10C (first insulating member) which has a frame shape (shape corresponding to a predetermined design) and is provided around the insulating member 10B with an opening section OP2 interposed therebetween, and a frame-like insulating member 10D (second insulating member) provided around the insulating member 10C with an opening section OP3 interposed therebetween.

In the example structure of the touch switch shown in FIG. 1, the glass substrate 2 has a dimension of width of 35 mm, length of 95 mm and thickness of 1.8 mm. The metal thin film has thickness of 1.1 μm. The non-transparent insulating film 10 has thickness of 10 μm.

The sensor unit 6 has a dimension of width of 15 mm and length of 15 mm. The leading-out wiring 8 has width of 30 μm. The lattice pattern of the line wirings 3 and 4 has line width of 15 μm and line pitch of 180 mm. The connection terminal 9 has a dimension of width of 4 mm and length of 0.5 mm.

A gap between one sensor unit 6 and another and a gap between the sensor unit 6 and the dummy sensor unit 7 is typically 0.2 mm. A gap between each electrode and each wiring is set to the minimum of 60 μm. A gap between one connection terminal 9 and another is 0.5 mm.

The metal thin film of the touch switch 1 having the above-mentioned dimensionality is formed by depositing a non-transparent film made of a material such as aluminum, aluminum alloy (e.g., aluminum-tantalum, etc.), niobium, molybdenum, gold, silver, copper or the like on the glass substrate 2 made of soda-lime glass or the like by using a sputtering process, a deposition process or a CVD process, and patterning this film using a photography technique. Alternatively, the metal thin film may be formed by forming a square lattice pattern (including leading-out wirings 8 thicker than line wirings) on the glass substrate 2 and then removing unnecessary portions of the line wirings to provide the separators 5.

In addition, the non-transparent insulating member 10 (insulating layer) is formed by printing and firing a paste made by mixing a coloring pigment such as a black pigment, a white pigment or the like with a low softening point glass frit.

The glass substrate 2 is of transparency. The glass substrate 2 may or may not be colored. The glass substrate 2 has thickness of equal to or less than few millimeters (less than 10 mm), preferably equal to or less than 3 mm from the standpoint of sensitivity of the sensor unit.

The metal thin film has thickness of equal to or less than 2 μm. Although not shown, the metal thin film formed on the glass substrate 2 includes an alignment mark, a mark indicating a cut position of the glass substrate, a model number, a lot number and so on.

The metal thin film may be made of different metal materials. However, forming this thin film with the same kind of metal material (sensor units 6, the dummy sensor units 7, the leading-out wirings 8, and the connection terminals 9) allows for simplification of manufacturing process and reduction of costs. In this case, the same kind of metal material may have a variation of metal composition in the same touch switch during manufacturing process. In addition, if a tempered glass substrate is employed and the manufacturing process is simplified using the same kind of metal material, it is possible to keep the strength of the tempered glass substrate constant because of the less number of times of heating and cooling.

With the above-structured touch switch 1, since the sensor units 6 and the dummy sensor units 7 are adjacent to each other at predetermined intervals and are electrically isolated from each other by the separators 5 provided in the square lattice pattern of line wirings 3 and 4 (some of the common lattice pattern), a gap between one sensor unit 6 and another or a gap between a sensor unit 6 and the dummy sensor unit 7 cannot has a band shape surrounded by two parallel line conductors. That is, since a dimension of a capacitor constituted by one sensor unit 6 and another or by a sensor unit 6 and a dummy sensor unit 7 is reduced, a basal capacitance can be reduced to improve detection sensitivity.

This is equally applied to a relationship between a leading-out wiring 8a and a sensor unit 6 or between a leading-out wiring 8a and a dummy sensor unit 7, thereby providing no band shape surrounded by two parallel line conductors.

Accordingly, a boundary between one sensor unit 6 and another or between a sensor unit 6 and a dummy sensor unit 7 and a boundary between a leading-out wiring 8a and a sensor unit 6 or between a leading-out wiring 8a and a dummy sensor unit 7 is less likely to be visible, thereby providing a prominent appearance.

In addition, since a capacitance between a sensor unit 6 and an adjacent sensor unit 6 or between a sensor unit 6 and a dummy sensor unit 7 and a capacitance between a leading-out wiring 8a and a sensor unit 6 or between a leading-out wiring 8a and a dummy sensor unit 7 are sufficiently reduced, it is possible to greatly improve precision of touch decision based on a difference in capacitance between touch state and non-touch state by sensitivity adjustment.

For a capacitance type touch switch, it is known that it is ideal if a count value (basal capacitance) for a non-touch decision is small while a change (change in capacitance) for a touch decision (including a state where an operator's fingertip is so close to a key area as to be decided as a touch even if the key area is not completely touched by the fingertip) is large. As described above, the reduction of capacitance leads to small basal capacitance.

The lattice pattern is not limited to the square but may have a shape in which first and second line wirings intersect with each other at any angles other than the right angle, such as a diamond shape and the like.

In addition, the leading-out wirings 8a may not be visible if they are led out in parallel to the line wirings 4 and/or the line wirings 3.

In addition, in the above-described embodiment, the width of the separators 5 is smaller than an arrangement interval between adjacent line wirings 3 and an arrangement interval between adjacent line wirings 4 and is larger than width of each of the line wirings 3 and 4. Accordingly, advantageously, ends of the line wirings 3 and 4 are necessarily adjacent to each other with the separators 5 interposed therebetween or one end of one line wiring is adjacent to the other line wiring with the separators 5 interposed therebetween at a boundary between one sensor unit 6 and another or between a sensor unit 6 and a dummy sensor unit 7 (or a boundary between a leading-out wiring 8a and a sensor unit 6 or between a leading-out wiring 8a and a dummy sensor unit 7).

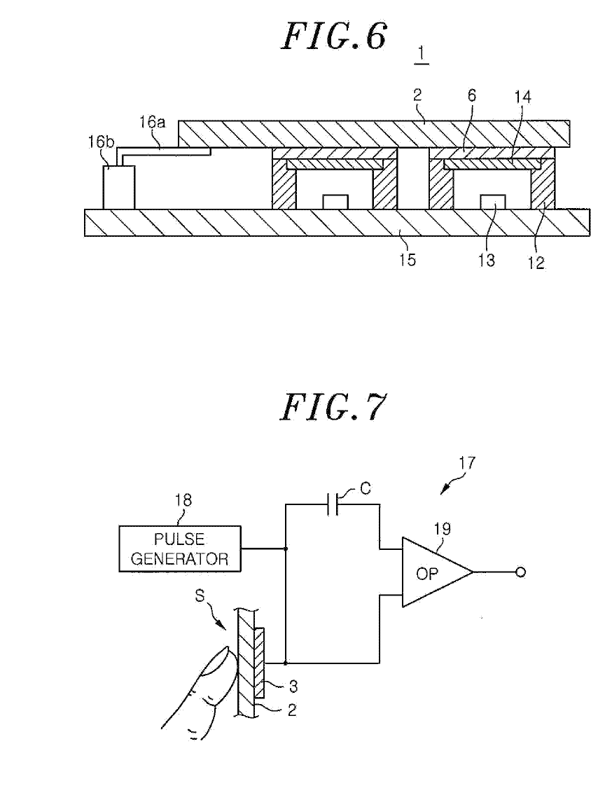

FIG. 6 is a sectional view showing a configuration example where light sources 19 for transmitting lights through marks are arranged in the touch switch 1 (which corresponds to a cross sectional view of the touch switch 1 taken along the line II-II in FIG. 1). FIG. 6 schematically shows only the sensor unit 6 (mark 11) of the metal thin films formed on the glass substrate 2 in the touch switch 1 shown in FIG. 1

As shown in FIG. 6, a tube-like case 12 is arranged at a position corresponding to the sensor unit 6 in the inner side of the glass substrate 2, with the case 12 in contact with the insulating layer 10. The case 12 is made of a non-transparent (light-shielding) material. A light source 13 is provided within the case 12. In this example, an LED is used for the light source 13. A diffuser 14 to remove a blur of light emitted from the LED is interposed between the LED and the insulating member 10. The tube-like case 12 prevents the light emitted from the LED from leaking into regions other than the sensor unit 6 and being visible from the outside of the glass substrate 2.

Electrical conduction to the light source 13 is carried out via a printed board 15. Transmission illumination for the mark 11 is controlled by the electrical conduction (ON) to/electrical interruption (OFF) from the light source 13. In this example, a plurality of light sources 13 (including the LED, the diffuser 14 and the tube-like case 12) is arranged to correspond to the marks 10 (the insulating member 10). In FIG. 6, 12 light sources are arranged for the marks 11 (in a one-to-one correspondence).

If the mark 11 includes the insulating member 10 and the opening section OP having a shape corresponding to the mark 11, the opening section OP (the mark 11) appears to be luminous when light passes through the opening section OP. If the mark 11 includes the opening section OP and the insulating member 10 having a shape corresponding to the mark 11, the non-transparent insulating member 10 (the mark 11) appears to be brought in relief when light passes through the opening section OP in the outside of a contour of the insulating member 10. If the mark 11 includes the first insulating member and the second insulating member provided therearound with the opening section OP interposed therebetween, the non-transparent first insulating member (the mark 11) appears to be brought in relief while the opening section OP (the mark 11) appears to be luminous when light passes through the opening section OP. Thus, the mark 11 can be clearly visible.

The touch switch 1 including the printed board 15 and the tube-like cases 12 are actually covered by a body case (not shown). The body case covers them such that a region of sensor units 6 of the touch switch 1 can be externally visible but other regions (the dummy sensor units 7, the connection terminals 9 and so on) cannot be externally visible.

In this example, for the illuminated touch switch of FIG. 6, circuit devices such as an LED drive circuit and so on are mounted on the printed board 15, and then, the diffuser 14 and the glass substrate 2 are mounted thereon via the tube-like case 12. Various types of circuits which are not mounted on the glass substrate 2 are mounted on the printed board 15, and the connection terminals 9 of the glass substrate 2 are connected to the printed board 15 via a flexible cable 16a and a connector 16b (members 16 for connection to the external). The connection terminals 9 are connected to the flexible cable 16a using an anisotropic conductive film (not shown) or the like.

FIG. 7 is a view used to explain the principle of operation of a touch switch in accordance with an embodiment of the present invention. As shown in FIG. 7, a touch detector 17 includes a pulse generator 18, a comparator 19 and a capacitor C connected between one input of the comparator 19 and the pulse generator 18, and a sensor unit 6 is connected between the pulse generator 18 and the other input of the comparator 19.

When the outer surface (touch portion S) of the glass substrate 2 corresponding to the sensor unit 6 is touched by an operator's finger (including a case where the finger is in proximity to the outer surface without the outer surface being touched by the finger), there occurs capacitance between the finger and the sensor unit 6, which serves as a kind of capacitor. It is configured that the capacitor C having the same capacitance as the sensor unit 6 under a condition of non-touch of the finger is connected between the one input of the comparator 19 and the pulse generator 18.

When the touch portion S is touched by the operator's finger, the touched outer surface of the glass substrate 2 acts as a dielectric and the capacitance of the sensor unit 6 is changed. Thus, a capacitance balance between the sensor unit 6 and the capacitor C is collapsed and a difference between pulse voltages applied to both inputs of the comparator 19 is produced to obtain an output from the comparator 19.

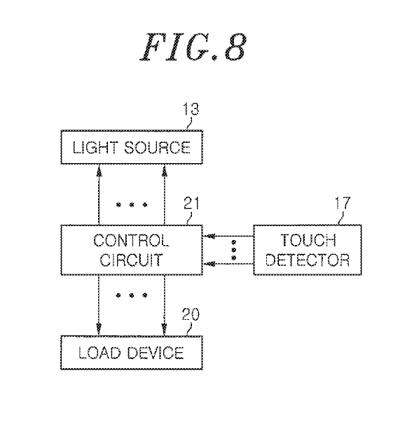

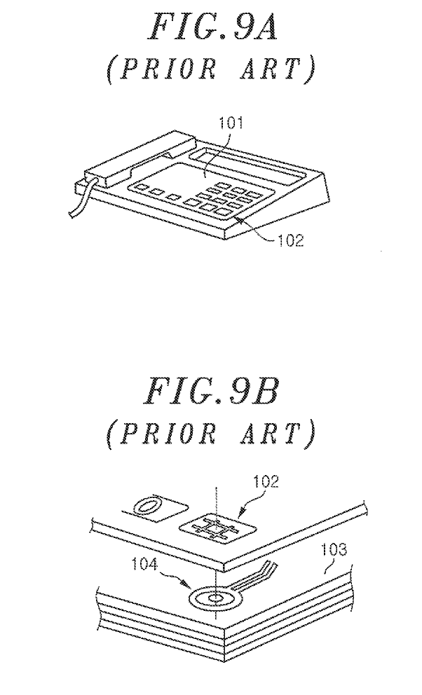

FIG. 8 is a circuit diagram of a touch switch having the light source of FIG. 7. As shown in FIG. 8, a circuit of the touch switch 1 includes a touch detector 17 (see FIG. 7) and a control circuit 21 for controlling a light source 13 and a load device 20.

Based on an output from the touch detector 17, the control circuit 21 turns on the light source 13 corresponding to the sensor unit 6 decided to be touched while turning on the load device 20 corresponding to the sensor unit 6 decided as being touched. Without being limited to this control, the control circuit 21 can freely set a touch operation, ON/OFF of the light source 13 and ON/OFF of the load device 20, in accordance with the load device 20.

If the light source 13 can emit lights with different colors (e.g., R, G and B lights), the light color from the light source 13 corresponding to the sensor unit 6 decided as being touched can be sequentially (R→G→B) changed. For example, if the load device 20 is an air conditioner or an audio system, the light color may be changed depending on a plurality of phases set for a set temperature or volume.

Moreover, with all light sources 13 emitting light of a predetermined color (e.g., R) initially, only a light source 13 corresponding to the sensor unit 6 decided as being touched may emit lights of a different color (e.g., R). Of course, a combination of two light emitting types and other colors than the red and the blue are possible.

Although, in the above-described embodiment, the number of marks 11 of the touch switch 1 is set to be equal to the number of light sources 13, they may be different from each other. For example, if the marks 11 are to be always illuminated, a single light source 13 may be provided for the marks 11. In addition, if a mark 11 has two designs, two light sources 13 may be provided to emit lights of different colors.

In the above-described embodiment, the light sources 13 have been arranged below the marks 11 of the touch switch 1 for transmission illumination. However, if the surroundings of the touch switch 1 is bright or a separate display is used to display a mark selection, a non-emission member (such as a colored film or the like) colored differently from that of the metal thin film may be adhered to or closely placed in the rear surfaces (surfaces facing the printed circuit board 15) of the marks 11 (transparent opening OP) of the glass substrate 2 so that the marks 10 can be brought in relief. The non-emission member may be arranged in a portion corresponding to each mark 11 or may be arranged in the entire rear surface of the glass substrate 2 forming the marks 11.

A separate insulating member (non-transparent or transparent) having a color different from that of the insulating member 10 may be used for the non-emission member. The separate insulating member is formed on the marks (transparent opening section OP) of the glass substrate 2 by printing or the like. The separate insulating member may be arranged in a portion corresponding to each mark 11 or may be arranged in the entire rear surface of the glass substrate 2 forming the marks 11.

In the above-described embodiment, the outer surface of the glass substrate 2 has been subjected to no process. However, the outer surface of the glass substrate 2 (a surface in the opposite side to a surface on which the sensor unit 6 and so on are formed) is preferably subjected to a surface treatment.

This surface treatment is carried out using ink made by mixing various resin beads (e.g., urethane beads or glass beads) into various resins (e.g., epoxy resin). This ink is applied on the outer surface of the glass substrate 2 of the touch switch 1 shown in FIGS. 1 to 8 and then is heated at about 100° C. and dried, thereby forming a coating film.

This coating film has a state where beads are dispersed in the resin and at least some beads are exposed to a surface of the coating film. Accordingly, since the outer surface of the glass substrate 2 is in a pseudo-etched (diffused surface-reflected) state, a fingerprint made by an operator's touch is unlikely to be visible and reflection by the metal thin film is prevented, which can result in a remarkable appearance. In addition, fine unevenness formed on the outer surface of the glass substrate 2 can improve an operator's touch sense.

While the invention has been shown and described with respect to the embodiments, it will be understood by those skilled in the art that various changes and modifications may be made without departing from the scope of the invention as defined in the following claims.

What is claimed is:

1. A touch switch, comprising:
a substrate;
a pattern formed on the substrate by a plurality of line wirings; and
a non-transparent insulating member formed on the line wirings,
wherein sensor units and dummy sensor units are formed to be electrically isolated from each other and adjacent to each other by separators provided in the line wirings of the pattern, and marks are formed by the non-transparent insulating member and a transparent opening section, the marks being arranged in positions corresponding to the sensor units.

2. The touch switch of claim 1, wherein the pattern has a lattice shape, and the line wirings include a plurality of first line wirings arranged at a predetermined interval and a plurality of second line wirings arranged at a predetermined interval to intersect the first line wirings.

3. The touch switch of claim 1, wherein the marks are formed by the insulating member and the opening section which is provided in the insulating member and has a shape corresponding to the marks.

4. The touch switch of claim 1, wherein the marks are formed by the opening section and the insulating member which is provided in the opening section and has a shape corresponding to the marks.

5. The touch switch of claim 1, wherein the insulating member includes a first insulating member and a second insulating member, and the marks are formed by the first insulating member having a shape corresponding to the marks and the second insulating member provided around the first insulating member with the opening section interposed therebetween.

6. The touch switch of claim 2, wherein the separators are provided in the first line wirings, and one separated ends of the separated first wirings are adjacent to the other separated ends of the separated first line wirings or one of the second line wirings with the separators interposed therebetween.

7. The touch switch of claim 2, wherein the separators are provided in the plurality of second line wirings, and one separated ends of the separated second wirings are adjacent to the other separated ends of the separated second line wirings or one of the first line wirings with the separators interposed therebetween.

8. The touch switch of claim 2, wherein the separators are provided in the first line wirings or the second line wirings, leading-out wirings of the sensor units are connected to the line wirings constituting the sensor units and are led out of the dummy sensor units via the separators; the leading-out wirings of the sensor units being adjacent to one separated ends of the first line wirings or one separated ends of the second line wirings with the separators interposed therebetween.

9. The touch switch of claim 1, wherein a coating film is provided on an opposite surface of the substrate to a surface on which the sensor units are formed, the coating film being made of resin into which beads are mixed, with at least some of the beads being exposed to a surface of the coating film.

10. The touch switch of claim 1, wherein a plurality of connection terminals is provided to connect an external connection member to the leading-out wirings and the dummy sensor units, and the sensor units, the dummy sensor units, the leading-out wirings of the sensor units, and the connection terminals on the substrate are made of a same metal thin film.

11. The touch switch of claim 1, further comprising light sources which illuminate the marks with light and are arranged to correspond to the marks.

12. The touch switch of claim 11, wherein the light sources emit lights with different colors and sequentially change light colors of the switch electrodes decided to be touched.

13. The touch switch of claim 11, wherein, in a state where all of the light sources emit light of a predetermined color, a light source corresponding to the switch electrode decided as being touched emits light of a different color.

14. The touch switch of claim 10, wherein a non-emission member having a color different from that of the metal thin film is formed on a rear surface of the marks.
